(19) United States
(12) Patent Application Publication
(10) Pub. No.: US 2026/0206551 A1
(43) Pub. Date: Jul. 16, 2026

(54) SEMICONDUCTOR STRUCTURE AND FABRICATION METHOD THEREOF

(71) Applicant: Vanguard International Semiconductor Corporation, Hsinchu (TW)

(72) Inventors: Chen-Dong Tzou, Taipei City (TW); Yun-Kai Lai, Taichung City (TW); Tzu-Hsuan Chen, Hsinchu City (TW); Chih-Cherng Liao, Hsinchu City (TW); Chia-Hao Lee, Hsinchu County (TW)

(73) Assignee: Vanguard International Semiconductor Corporation, Hsinchu (TW)

(21) Appl. No.: 19/026,282

(22) Filed: Jan. 16, 2025

(51) Int. Cl. H01L 21/762; H10D 30/65; H10D 30/66; H10D 86/00; H10D 86/01

(52) U.S. Cl. CPC H10P 90/1906; H10D 86/00; H10D 86/01; H10P 90/1914; H10W 10/014; H10W 10/061; H10W 10/17; H10W 10/181; H10D 30/657; H10D 30/667

(57) ABSTRACT

A semiconductor structure includes a base, at least one epitaxial layer, a deep trench isolation structure, a patterned isolation layer, and a conductive layer. The base has a first conductivity type, and the epitaxial layer is disposed on the base. The deep trench isolation structure penetrates the epitaxial layer and the base. The deep trench isolation structure surrounds a first area, and a second area is located outside the deep trench isolation structure. The patterned isolation layer is disposed on the bottom surface of the base and has an opening to expose the base in the second area. The conductive layer is disposed under the patterned isolation layer, and is electrically connected to the base through the opening.

### BACKGROUND OF THE INVENTION

### 1. Field of the Invention

The present disclosure relates generally to semiconductor technology, and more particularly to semiconductor structures including a local isolation region and fabrication methods thereof.

### 2. Description of the Prior Art

With the evolution of integrated circuit manufacturing technology, various components including lateral components (e.g., complementary metal-oxide-semiconductor field-effect transistors (CMOSFET)), in which current flows horizontally, and vertical components (e.g., dynamic random-access memory (DRAM)), in which current flows vertically, may be integrated in a monolithic substrate. The monolithic substrate usually requires a local isolation structure to isolate lateral and vertical components. Generally, a junction isolation region or a partial silicon-on-insulator (partial SOI) region may be used as the local isolation structure. However, the depth of the junction isolation region is limited by the ion implanter's implantation energy. The major processes for forming the partial SOI region include separation by implantation of oxygen (SIMOX) and smart-cut processes, which have many problems that need to be overcome.

### SUMMARY OF THE INVENTION

In view of this, the present disclosure provides semiconductor structures and fabrication methods thereof. A deep trench isolation structure and a patterned isolation layer located on the backside of a base are used to constitute a local isolation region in the semiconductor structures. The combination of the deep trench isolation structure and the patterned isolation layer isolates lateral and vertical devices integrated on a monolithic chip. The semiconductor structures avoid problems associated with junction isolation regions and partial SOI regions. Moreover, the semiconductor structures effectively prevent lateral devices from being affected by high potentials of vertical devices. Therefore, the semiconductor structures of the present disclosure are more suitable for high-voltage applications (e.g., greater than 80V).

According to an embodiment of the present disclosure, a semiconductor structure is provided and includes a base, at least one epitaxial layer, a deep trench isolation structure, a patterned isolation layer, and a conductive layer. The base has a first conductivity type, and the epitaxial layer is disposed on the base. The deep trench isolation structure penetrates both the epitaxial layer and the base. The deep trench isolation structure surrounds a first area, and a second area is located outside the deep trench isolation structure. The patterned isolation layer is disposed on the bottom surface of the base and has an opening to expose the base in the second area. The conductive layer is disposed under the patterned isolation layer and is electrically connected to the base through the opening.

According to an embodiment of the present disclosure, a method of fabricating a semiconductor structure is provided and includes the following steps. A base having a first conductivity type is provided and includes a first surface opposite to a second surface. An epitaxial layer is formed on the first surface of the base. A deep trench isolation structure is formed in the epitaxial layer and the base. The deep trench isolation structure surrounds a first area, and a second area is located outside the deep trench isolation structure. A grinding process is performed on the second surface of the base to thin the base and expose the deep trench isolation structure. An isolation material layer is deposited on the second surface of the base after the base is thinned, and the isolation material layer is in direct contact with a bottom surface of the deep trench isolation structure. The isolation material layer is patterned to form a patterned isolation layer having an opening to expose the base in the second area. In addition, a conductive layer is formed under the patterned isolation layer and is electrically connected to the base through the opening.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a semiconductor structure according to an embodiment of the present disclosure.

FIG. 2 is a schematic cross-sectional view of a semiconductor structure according to another embodiment of the present disclosure.

FIG. 3, FIG. 4, FIG. 5, FIG. 6, FIG. 7, FIG. 8 and FIG. 9 are schematic cross-sectional views of some stages of a method of fabricating a semiconductor structure according to an embodiment of the present disclosure.

FIG. 10 shows schematic cross-sectional views of some intermediate stages of a method of fabricating a semiconductor structure according to another embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “over,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “beneath” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

According to embodiments of the present disclosure, a deep trench isolation structure and a patterned isolation layer on the backside of a base constitute a local isolation region to isolate lateral and vertical devices integrated on a monolithic chip. The deep trench isolation structure and the patterned isolation layer together surround the lateral devices without blocking electron flow in the vertical devices to the base. In the off-state, the lateral devices are unaffected by the high potentials of the vertical devices. Therefore, the semiconductor structures of the present disclosure are suitable for higher-voltage applications (e.g., greater than 80V). Moreover, according to the semiconductor structures of the present disclosure and fabrication methods thereof, forming a junction isolation region and/or a partial SOI region is unnecessary. Therefore, the problem of the junction isolation region depth being limited by the ion implantation energy is avoided. In addition, epitaxial defects and step-height issues associated with partial SOI region are also avoided.

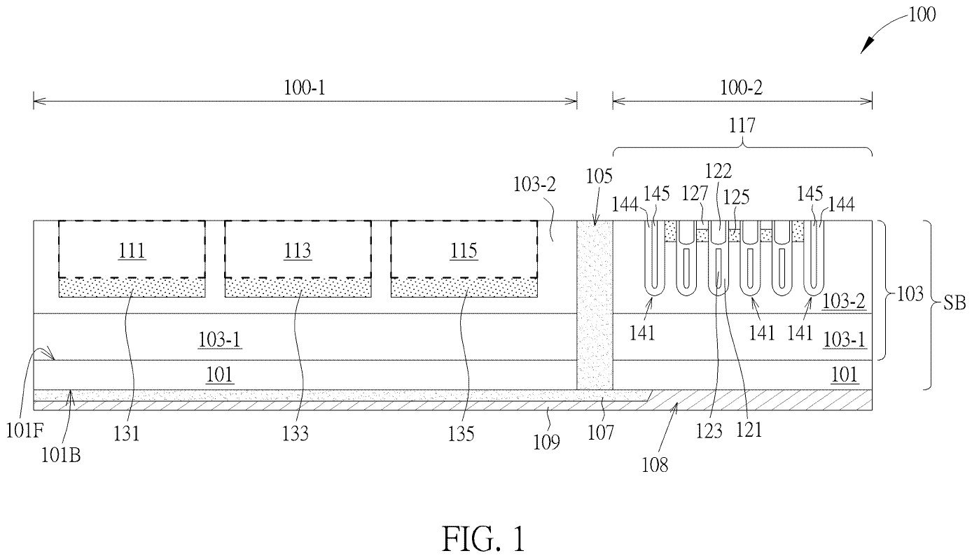

FIG. 1 is a schematic cross-sectional view of a semiconductor structure 100 according to an embodiment of the present disclosure. The semiconductor structure 100 includes a base 101 having a first conductivity type, such as an n-type heavily doped silicon base. The base 101 includes a first surface 101F (or referred to as an upper surface) opposite to a second surface 101B (or referred to as a bottom surface). An epitaxial stack 103 is disposed on the first surface 101F of the base 101. The epitaxial stack 103 also has the first conductivity type, such as an n-type silicon epitaxial stack. The base 101 and the epitaxial stack 103 constitute a monolithic substrate SB. In one embodiment, the epitaxial stack 103 includes a first epitaxial layer 103-1 and a second epitaxial layer 103-2, which are stacked on the base 101 from bottom to top, but is not limited thereto. The epitaxial stack 103 may include one, three or more epitaxial layers. In addition, the composition, the doping concentration of first conductive type dopants, and/or the thickness of the first epitaxial layer 103-1 may be different from those of the second epitaxial layer 103-2. In some embodiments, the composition of the base 101 is, for example, silicon (Si), silicon carbide (SiC), or other suitable semiconductor materials. The composition of the epitaxial stack 103 is, for example, silicon (Si), silicon germanium (SiGe), silicon carbide (SiC), gallium nitride (GaN), gallium arsenide (GaAs), indium phosphide (InP) or other suitable semiconductor materials.

According to some embodiments of the present disclosure, the semiconductor structure 100 includes a deep-trench-isolation (DTI) structure 105 that penetrates both the epitaxial stack 103 and the base 101, and extends downward from the top surface of the epitaxial stack 103 to the second surface 101B of the base 101. The DTI structure 105 surrounds a first area 100-1 of the semiconductor structure 100, and the area outside the DTI structure 105 includes a second area 100-2 of the semiconductor structure 100. The cross-sectional view of FIG. 1 only shows a portion of the DTI structure 105 located on the right side of the first area 100-1. In a top view, the DTI structure 105 may completely surround the first area 100-1, and the second area 100-2 is located on the right side of the DTI structure 105. Multiple lateral devices, such as an n-type laterally double-diffused metal-oxide-semiconductor (N-LDMOS) transistor 111, a p-type laterally double-diffused metal-oxide-semiconductor (P-LDMOS) transistor 113, and a complementary metal-oxide-semiconductor (CMOS) transistor 115, are disposed in the epitaxial stack 103 of the first area 100-1, but are not limited thereto. Other lateral device, such as a bipolar transistor, may be also disposed in the epitaxial stack 103 of the first area 100-1. These lateral devices in the first area 100-1 construct a bipolar-CMOS-DMOS integrated structure, also referred to as a BCD structure.

In addition, multiple vertical devices, such as a vertically double-diffused metal-oxide-semiconductor (VDMOS) transistor 117, an insulated gate bipolar transistor (IGBT), a trench metal-oxide-semiconductor (trench MOS) transistor and/or other vertical devices, are disposed in the epitaxial stack 103 of the second area 100-2. The VDMOS transistor 117 includes multiple trenches 141 disposed in the epitaxial stack 103 of the second area 100-2. A gate electrode 122, a field plate 123 and a dielectric layer 121 are disposed in each trench 141 in an active area. The gate electrode 122 is located directly above the field plate 123. The dielectric layer 121 surrounds the gate electrode 122 and the field plate 123, and longitudinally separates the gate electrode 122 from the field plate 123. Body regions 125 are disposed on two sides of each trench 141 in the active area. The body regions 125 are, for example, p-type well regions. Source regions 127 are respectively disposed in the body regions 125 in the active area. The source regions 127 are, for example, n-type heavily doped regions. In addition, a field plate 145 and a dielectric layer 144 are disposed in the trench 141 outside the active area. The dielectric layer 144 surrounds the field plate 145. The base 101 is, for example, an n-type heavily doped silicon base. The base 101 in the second area 100-2 constitutes a drain region of the VDMOS transistor 117. The electron flow in the VDMOS transistor 117 flows vertically from the source region 127 to the base 101 in the second area 100-2.

Moreover, the semiconductor structure 100 includes a patterned isolation layer 107 disposed on the second surface 101B (the bottom surface) of the base 101. The patterned isolation layer 107 has an opening 108 to expose the base 101 in the second area 100-2. In some embodiments, in a top view, the area of the opening 108 may be substantially equal to or smaller than the area of the VDMOS transistor 117. The semiconductor structure 100 further includes a conductive layer 109 disposed under the patterned isolation layer 107. The conductive layer 109 is electrically connected to the base 101 in the second area 100-2 through the opening 108. The conductive layer 109 can serve as a drain electrode of the VDMOS transistor 117. In one embodiment, the conductive layer 109 is a metal layer, and its composition may include gold, titanium, silver, copper, aluminum-copper, or other suitable metals or alloys. The conductive layer 109 covers the bottom and side surfaces of the patterned isolation layer 107, and is in direct contact with the base 101 in the second area 100-2.

As shown in FIG. 1, the bottom surface of the DTI structure 105 is in direct contact with the top surface of the patterned isolation layer 107. In a top view, the boundary of the patterned isolation layer 107 is beyond the boundary of the DTI structure 105. The DTI structure 105 and the patterned isolation layer 107 completely surround multiple lateral devices in the first area 100-1, including the N-LDMOS transistor 111, the P-LDMOS transistor 113, the CMOS transistor 115 and other lateral devices. The DTI structure 105 and the patterned isolation layer 107 constitute a local isolation region without blocking the electron flow in vertical devices such as the VDMOS transistor 117 in the second area 100-2, which flows vertically to the base 101. The VDMOS transistor 117 can serve as a power integrated circuit (power IC) component and is suitable for high-voltage and high-current operating conditions. The DTI structure 105 and the patterned isolation layer 107 effectively prevent the lateral devices in the first area 100-1 from being affected by the high potentials of the vertical devices in the second area 100-2. Moreover, the DTI structure 105 and the patterned isolation layer 107 avoid the electrostatic discharge (ESD) latch-up effect caused by current noise from the vertical devices. Therefore, the semiconductor structure 100 of the present disclosure is suitable for higher-voltage applications (e.g., greater than 80V).

Furthermore, in the semiconductor structure 100 of FIG. 1, a first buried layer 131, a second buried layer 133 and a third buried layer 135 may be disposed in the epitaxial stack 103 of the first area 100-1, and directly below the N-LDMOS transistor 111, the P-LDMOS transistor 113 and the CMOS transistor 115, respectively. The first buried layer 131, the second buried layer 133 and the third buried layer 135 all have a second conductivity type different from the first conductivity type of the epitaxial stack 103, for example, they are all p-type buried layers. A junction isolation effect is generated between the n-type epitaxial stack 103 and each of the first buried layer 131, the second buried layer 133 and the third buried layer 135, thereby providing junction isolation regions for the N-LDMOS transistor 111, the P-LDMOS transistor 113 and the CMOS transistor 115, respectively.

In one embodiment, the deep trench of the DTI structure 105 may be filled up with an insulating material, such as silicon oxide, silicon nitride, silicon oxynitride, other suitable organic insulating materials, or a combination thereof. The composition of the patterned isolation layer 107 may be the same as the insulating material filling in the DTI structure 105. For example, the deep trench of the DTI structure 105 may be filled up with silicon oxide, and the patterned isolation layer 107 may be a silicon oxide layer, but are not limited thereto. The composition of the patterned isolation layer 107 may be different from the insulating material filling in the DTI structure 105. In addition, the thickness of the patterned isolation layer 107 may be adjusted according to the voltage rating of the vertical devices in the second area 100-2. When the operating voltage of the VDMOS transistor 117 is higher, the thickness of the patterned isolation layer 107 is increased. For example, when the operating voltage of the VDMOS transistor 117 is 80V or higher, the thickness of the patterned isolation layer 107 may be adjusted to 0.3 μm or more.

In another embodiment, the DTI structure 105 may be filled with a dielectric layer and a semiconductor material. In the DTI structure 105, the dielectric layer conformally lines the inner sidewalls of the deep trench, and the semiconductor material fills up the deep trench. The composition of the dielectric layer is, for example, silicon oxide, silicon nitride, silicon oxynitride or a combination thereof. The semiconductor material may be polysilicon. For a deep trench with a high aspect ratio, the semiconductor material has better void-filling capacity than the dielectric layer, and can fill the deep trench of the DTI structure 105 with few or no voids. Moreover, when the DTI structure 105 is filled with semiconductor material, the bias voltage of the DTI structure 105 may be a floating potential. Alternatively, the DTI structure 105 may be configured to be connected to a ground voltage. Therefore, the DTI structure 105 can prevent interference between the lateral devices in the first area 100-1 and the vertical devices in the second area 100-2.

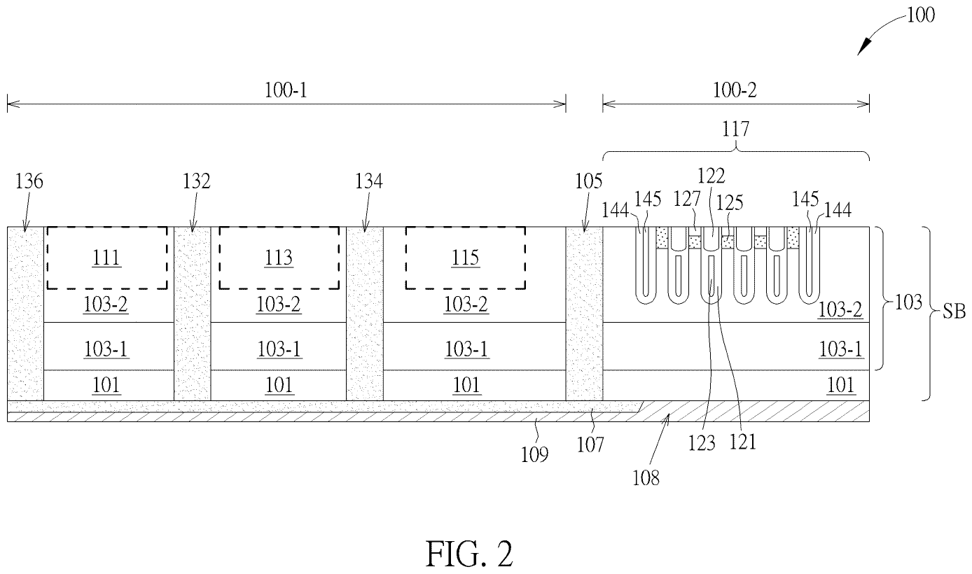

FIG. 2 is a schematic cross-sectional view of a semiconductor structure 100 according to another embodiment of the present disclosure. In this embodiment, the semiconductor structure 100 further includes a first sub-DTI structure 132, a second sub-DTI structure 134 and a third sub-DTI structure 136 disposed in the first area 100-1. These sub-DTI structures all penetrate the epitaxial stack 103 and the base 101, and the bottom surfaces of these sub-DTI structures are all in direct contact with the top surface of the patterned isolation layer 107. The first sub-DTI structure 132 is disposed between the N-LDMOS transistor 111 and the P-LDMOS transistor 113. The second sub-DTI structure 134 is disposed between the P-LDMOS transistor 113 and the CMOS transistor 115. The third sub-DTI structure 136 isolates the N-LDMOS transistor 111 from other components in the first area 100-1.

In one embodiment, these sub-DTI structures in the first area 100-1 have the same composition, the same depth, and the same width as those of the DTI structure 105. In another embodiment, these sub-DTI structures in the first area 100-1 all have the same composition, the same depth and the same width, and the composition and the width of these sub-DTI structures are different from those of the DTI structure 105. For example, these sub-DTI structures may be filled up with an insulating material, and the DTI structures 105 may be lined with a dielectric layer and filled up with a semiconductor material. Moreover, the width of these sub-DTI structures may be smaller than the width of the DTI structures 105. Moreover, in the semiconductor structure 100 of FIG. 2, no junction isolation region is disposed directly below the lateral devices in the first area 100-1. For example, no p-type buried layer is disposed directly below the N-LDMOS transistor 111, the P-LDMOS transistor 113 and the CMOS transistor 115. The first sub-DTI structure 132, the second sub-DTI structure 134, and the third sub-DTI structure 136 can provide good isolation between the N-LDMOS transistor 111, the P-LDMOS transistor 113 and the CMOS transistor 115. Details of other features of the semiconductor structure 100 in FIG. 2 may refer to the aforementioned descriptions of the semiconductor structure 100 in FIG. 1, and will not be repeated here.

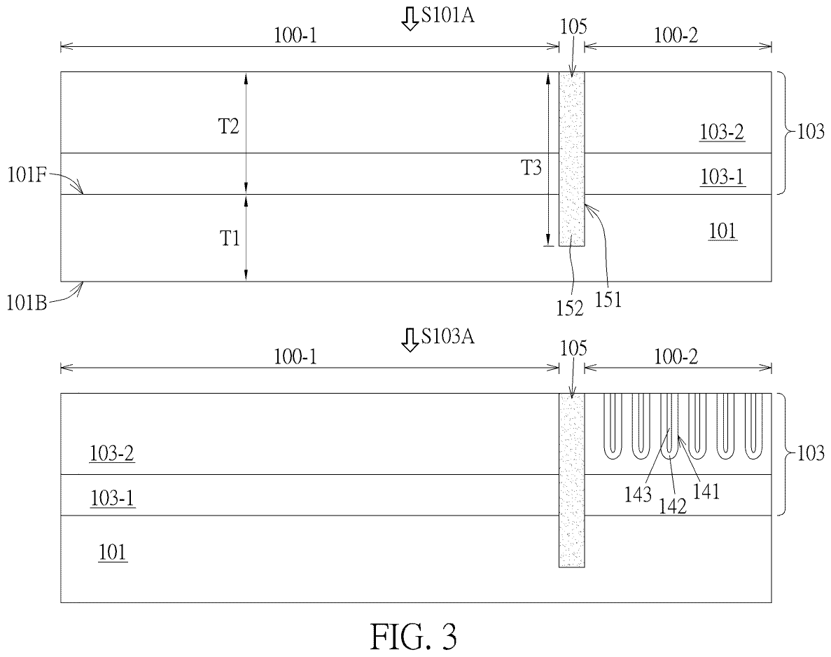

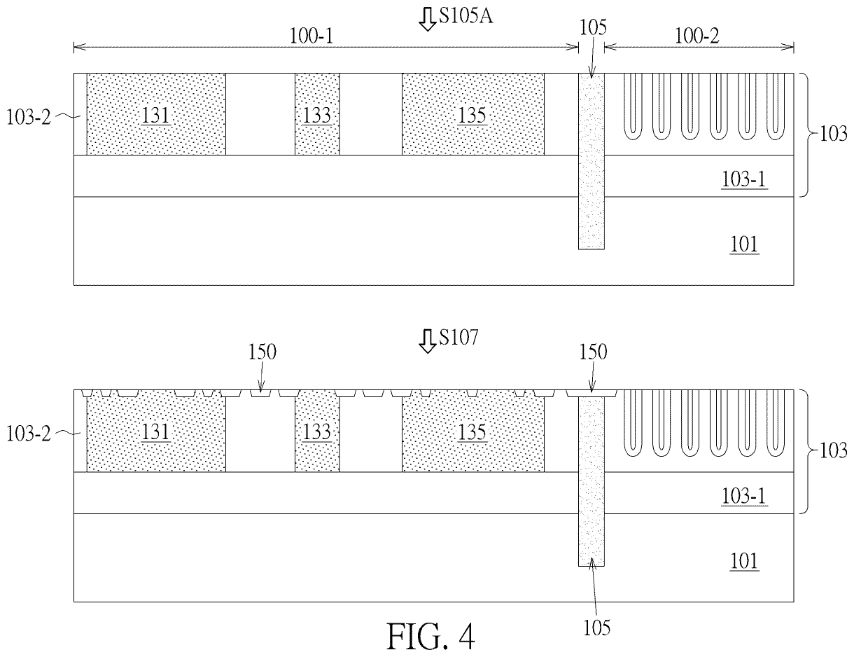

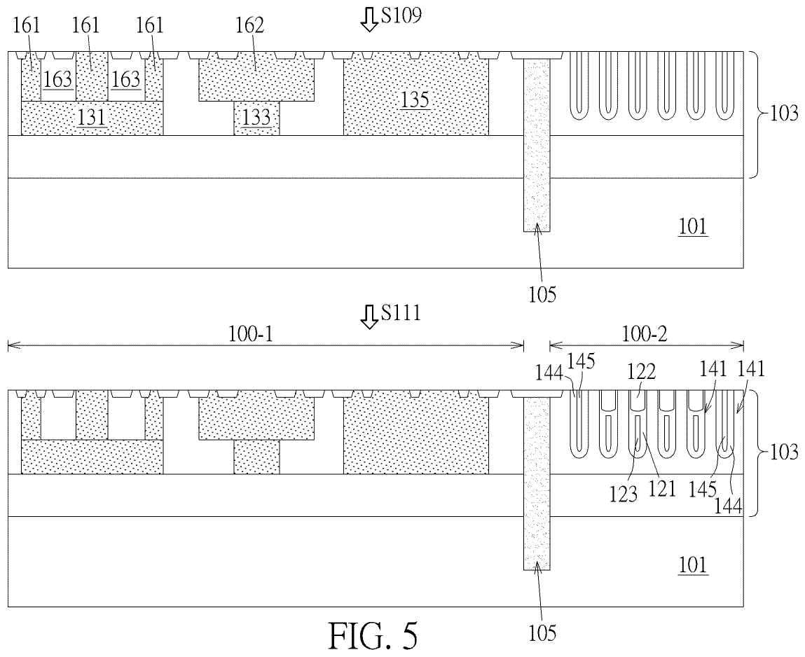

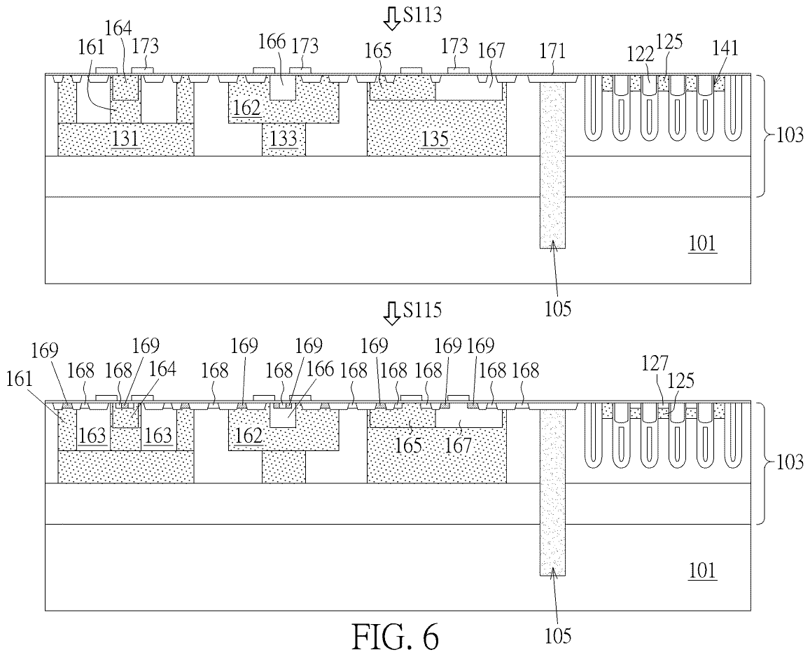

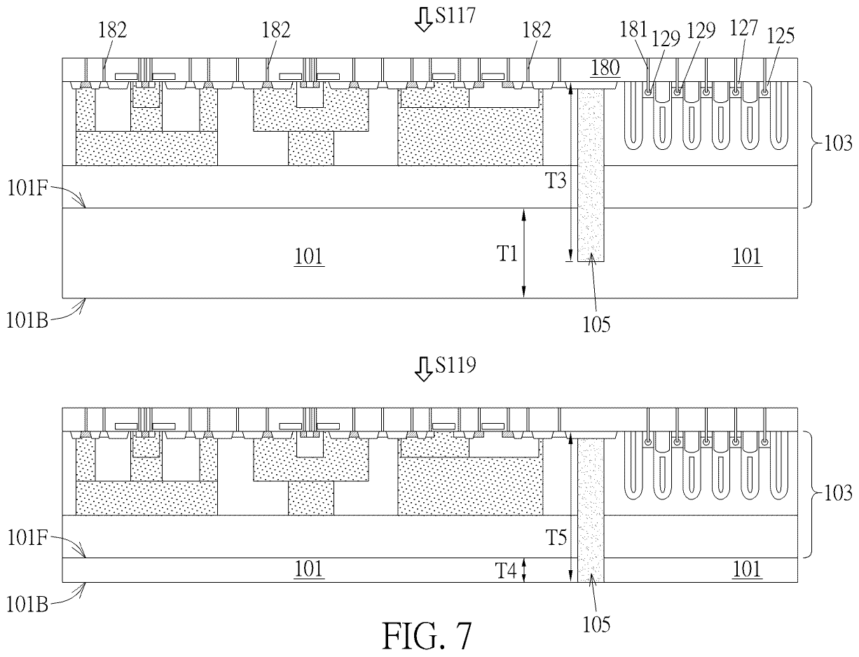

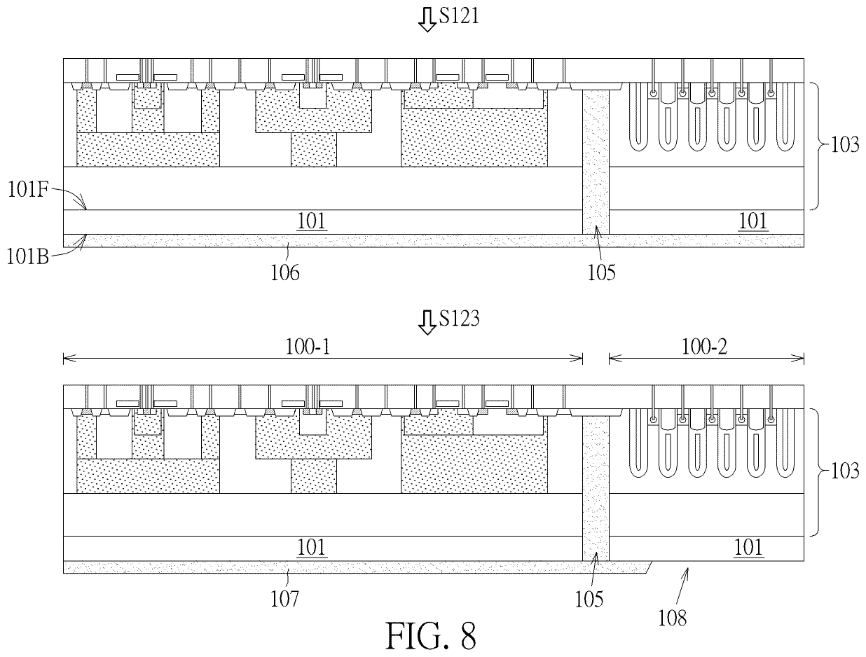

FIG. 3, FIG. 4, FIG. 5, FIG. 6, FIG. 7, FIG. 8 and FIG. 9 are schematic cross-sectional views of some stages of a method of fabricating a semiconductor structure 100 according to an embodiment of the present disclosure. Referring to FIG. 3, in step S101A, firstly, a base 101 with a first conductivity type, such as an n-type heavily doped silicon base, is provided. The base 101 has a first surface 101F opposite to a second surface 101B. In step S101A, the base 101 has an initial thickness T1. A first epitaxial layer 103-1 and a second epitaxial layer 103-2 are grown on the first surface 101F of the base 101 in sequence. These epitaxial layers both have the first conductivity type, such as n-type silicon epitaxial layer. The first epitaxial layer 103-1 and the second epitaxial layer 103-2 constitute an epitaxial stack 103, and the epitaxial stack 103 has a thickness T2. Next, a deep trench 151 with a high aspect ratio is formed in in the epitaxial stack 103 and the base 101 by etching such as a deep reactive ion etching (DRIE) process. The aspect ratio of the deep trench 151 is, for example, greater than 50. The deep trench 151 extends downward from the top surface of the epitaxial stack 103, penetrating the epitaxial stack 103 and reaching the base 101. The bottom surface of the deep trench 151 is located in the base 101. The deep trench 151 is filled up with a filling material 152 by deposition and chemical mechanical planarization (CMP) processes to form a deep trench isolation (DTI) structure 105. The DTI structure 105 surrounds a first area 100-1, and the area outside the DTI structure 105 includes a second area 100-2.

In one embodiment, the filling material 152 is an insulating material such as silicon oxide. In another embodiment, the filling material 152 includes a dielectric layer and a semiconductor material. The dielectric layer is, for example, a silicon oxide layer, and conformally deposited on the inner sidewalls and the bottom surface of the deep trench 151. The semiconductor material such as polysilicon fills up the deep trench 151, and the dielectric layer surrounds the semiconductor material. In step S101A, the deep trench 151 of the DTI structure 105 has a depth T3, and the depth T3 is adjusted according to a target depth of the DTI structure 105 in the semiconductor structure. For example, when the target depth of the DTI structure 105 is 100 μm, the depth T3 of the deep trench 151 may be 120 μm to 150 μm. The initial thickness T1 of the base 101 may be 750 μm, and the thickness T2 of the epitaxial stack 103 may be 10 μm. In addition, the width of the deep trench 151 is determined by the aspect ratio and depth T3 of the deep trench 151 that can be achieved by the etching process.

Still referring to FIG. 3, in step S103A, multiple trenches 141 of a VDMOS transistor are formed by etching in the epitaxial stack 103 of the second area 100-2. A dielectric liner 142 is conformally formed in each trench 141, and then each trench 141 is filled up with a semiconductor material 143 such as polysilicon by deposition and CMP processes. The semiconductor material 143 is surrounded by the dielectric liner 142.

Next, referring to FIG. 4, in step S105A, a first buried layer 131, a second buried layer 133 and a third buried layer 135 are simultaneously formed in the epitaxial stack 103 of the first area 100-1 by ion implantation and using a patterned mask. These buried layers are laterally separated from each other and all have a second conductivity type, such as p-type buried layers (PBL). Moreover, these buried layers have the same doping concentration and the same depth. Still referring to FIG. 4, in step S107, multiple shallow trench isolation (STI) regions 150 are formed on the top surface of the epitaxial stack 103 in the first area 100-1 and on the DTI structure 105 by etching, deposition and CMP processes. These STI regions 150 separate multiple subsequently formed doped regions having different conductivity types in lateral devices of the first area 100-1.

Then, referring to FIG. 5, in step S109, three well regions 161 in the first buried layer 131 and a well region 162 in the epitaxial stack 103 corresponding the second buried layer 133 are simultaneously formed by ion implantation and using a patterned mask. All the well regions 161 and the well region 162 have the second conductivity type, such as high-voltage p-type well (HVPW) regions. Afterwards, two well regions 163 are formed in the first buried layer 131 by another ion implantation and using another patterning mask. Each well region 163 is located between two well regions 161. These well regions 163 have the first conductivity type, such as high-voltage n-type well (HVNW) regions.

Still referring to FIG. 5, in step S111, in the second area 100-2, except for the outermost trench 141 (outside an active area), a portion of the semiconductor material 143 in the trenches 141 of the active area is removed by etching, thereby forming field plates 123. The trenches 141 in the active area are filled with a dielectric material to cover the field plates 123 by deposition. Next, the dielectric material located above the field plates 123 is etched to form a recess in each trench 141 of the active area. A gate dielectric layer is conformally formed in each recess by deposition or thermal oxidation. Afterwards, these recesses are filled up with a semiconductor material to form multiple gate electrodes 122. The dielectric material in each trench 141 of the active area constitutes a dielectric layer 121 to surround the gate electrode 122 and the field plate 123. The dielectric material in each trench 141 of the active area also longitudinally separates the gate electrode 122 from the field plate 123. The semiconductor material 143 in the outermost trench 141 outside the active area constitutes a field plate 145, and the dielectric liner 142 in the outermost trench 141 constitutes a dielectric layer 144 to surround the field plate 145.

Next, referring to FIG. 6, in step S113, a well region 164 in the middle well region 161 above the first buried layer 131, and a well region 165 in the third buried layer 135 are simultaneously formed by ion implantation and using a patterned mask. The well region 164 and the well region 165 both have the second conductivity type, such as p-type well (PW) regions. Then, a well region 166 in the well region 162 and a well region 167 in the third buried layer 135 are simultaneously formed by another ion implantation and using another patterning mask, where the well region 167 abuts the well region 165. Both the well region 166 and the well region 167 have the first conductivity type, such as n-type well (NW) regions. Afterwards, a dielectric layer 171 is deposited on the entire top surface of the epitaxial stack 103. The dielectric layer 171 located in the first area 100-1 can serves as a gate dielectric layer. Next, multiple gate electrodes 173 are formed on the dielectric layer 171 in the first area 100-1 by deposition and patterning processes. Two of these gate electrodes 173 are located on two sides of the well region 164. Two of these gate electrodes 173 are located on two sides of the well region 166. Two of these gate electrodes 173 are located directly above the well region 165 and the well region 167, respectively. Then, multiple body regions 125 such as p-type body regions are formed in the epitaxial stack 103 of the second area 100-2 by ion implantation and using a patterned mask. These body regions 125 are located on two sides of each gate electrode 122.

Still referring to FIG. 6, in step S115, multiple doped regions 168 are formed in the well region 163, the well region 164, the well region 166, the well region 165 and the well region 167, and also in the epitaxial stack 103 of the first area 100-1 by ion implantation and using a patterned mask. Meanwhile, source regions 127 are respectively formed in the body regions 125 by the aforementioned ion implantation and using the same patterned mask. These doped regions 168 and these source regions 127 all have the first conductivity type, such as n-type heavily doped regions. Moreover, multiple doped regions 169 are formed in the well region 161, the well region 164, the well region 162, the well region 166, the well region 165, and the well region 167 by another ion implantation and using another patterning mask. These doped regions 169 all have the second conductivity type, such as p-type heavily doped regions.

Next, referring to FIG. 7, in step S117, an interlayer dielectric (ILD) layer 180 is deposited on the entire top surface of the epitaxial stack 103 to cover the gate electrodes 173. Multiple holes of contacts 181 are formed by etching in the ILD layer 180 of the second area 100-2. These holes extend downward into the body regions 125, and some of the holes penetrate the source regions 127. Then, multiple doped regions 129 are formed in the body regions 125 by ion implantation through the holes of the contacts 181. The doped regions 129 are located directly below the holes, and have the second conductivity type, such as p-type heavily doped regions. Afterwards, the holes of contacts 181 are filled up with a conductive material to form multiple contacts 181 of the VDMOS transistor. Then, multiple holes for contacts 182 are formed by etching in the ILD layer 180 of the first area 100-1. These holes respectively expose the doped regions 168 and the doped regions 169. Afterwards, these holes are filled up with a conductive material to form multiple contacts 182 of the N-LDMOS transistor, the P-LDMOS transistor and the CMOS transistor. In step S117, all back-end-of-line (BEOL) processes on the front side of the semiconductor structure to the passivation layer are completed.

Still referring to FIG. 7, in step S119, a carrier such as a glass substrate is bonded to the ILD layer 180 of the structure in step S117, and then the structure in step S117 is turned upside down. Then, a grinding process is performed on the second surface 101B of the base 101 to thin the thickness of the base 101 until expose the DTI structure 105. Before the grinding process in step S119, the N-LDMOS transistor, the P-LDMOS transistor and the CMOS transistor are formed in the epitaxial stack 103 of the first area 100-1, and the VDMOS transistor is also formed in the epitaxial stack 103 of the second area 100-2. After the grinding process in step S119 is completed, the thickness of the base 101 is reduced from the initial thickness T1 to a thickness T4. Moreover, the grinding process in step S119 also removes a portion of the filling material in the DTI structure 105. In one embodiment, this grinding process can remove the insulating material at the bottom of the DTI structure 105. In another embodiment, this grinding process can remove the dielectric layer and the semiconductor material at the bottom of the DTI structure 105 to expose the semiconductor material. Through the semiconductor material in the DTI structure 105, the bias voltage of the DTI structure 105 may be at a floating potential, or the DTI structure 105 may be configured to be connected to a ground voltage. After the grinding process of step S119 is completed, the DTI structure 105 has a depth T5 smaller than the depth T3 of the deep trench 151 in steps S101A to step S117. In some embodiments, the depth T5 is, for example, about 100 μm to 110 μm, and the depth T3 is, for example, about 120 μm to 150 μm.

Next, referring to FIG. 8, in step S121, an isolation material layer 106, such as a silicon oxide layer, is deposited on the entire second surface 101B of the base 101. The isolation material layer 106 covers the DTI structure 105, and is in direct contact with the bottom surface of the DTI structure 105. In some embodiments, when the voltage rating of the VDMOS transistor is 80V, the thickness of the isolation material layer 106 may be about 0.3 μm. The thickness of the isolation material layer 106 is increased according to the increase in the voltage rating of the VDMOS transistor.

Still referring to FIG. 8, in step S123, the isolation material layer 106 is patterned by etching and using a patterned hard mask to form a patterned isolation layer 107 having an opening 108 to expose the base 101 in the second area 100-2. The base 101 in the second area 100-2 constitutes a drain region of the VDMOS transistor. The area of the opening 108 of the patterned isolation layer 107 may be substantially equal to or smaller than the area of the VDMOS transistor.

Next, referring to FIG. 9, in step S125, backside metallization is performed on the second surface 101B of the base 101 by evaporation or sputtering deposition to form a conductive layer 109 under the patterned isolation layer 107. The conductive layer 109 is electrically connected to the base 101 in the second area 100-2 that serve as the drain region through the opening 108 of the patterned isolation layer 107. Therefore, the conductive layer 109 serves as a drain electrode of the VDMOS transistor 117 to provide a drain potential D. In some embodiments, the conductive layer 109 is a metal layer including titanium (Ti), nickel (Ni), silver (Ag), tin (Sn), copper (Cu), gold (Au), aluminum copper (AlCu), other metals or alloys. Alternatively, the conductive layer 109 is a multi-layered metal stack, such as a metal stack of Ti/Ni/Ag, Ti/Ni/Ti/Ag, Ti/Ni/Ag/Ni, or Ti/Ni/Ag/Sn. In addition, the conductive layer 109 covers the bottom and side surfaces of the patterned isolation layer 107 and fills up the opening 108 to be in direct contact with the base 101 in the second area 100-2.

In addition, as shown in FIG. 9, some contacts in the ILD layer 180 respectively provide a source potential S, a drain potential D and a gate potential G to the N-LDMOS transistor 111, the P-LDMOS transistor 113 and the CMOS transistor 115. Some contacts in the ILD layer 180 provide a substrate potential Sub to the epitaxial stack 103 in the first area 100-1. Some contacts in the ILD layer 180 provide a bulk potential B to the CMOS transistor 115. Other contacts in the second area 100-2 provide a source potential S to the VDMOS transistor 117. Other contacts (not shown) are disposed in the second area 100-2 to provide a gate potential G to the VDMOS transistor 117. The field plates in the trenches of the VDMOS transistor 117 are electrically coupled to the source potential S.

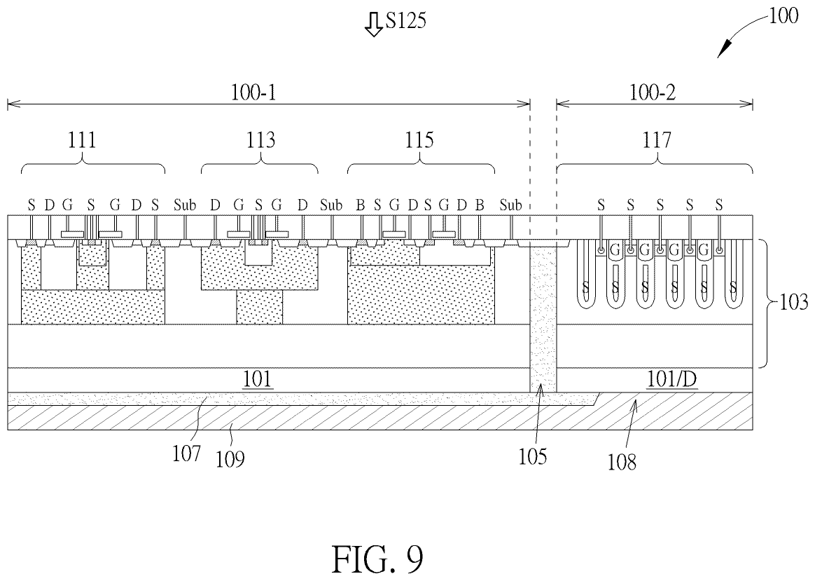

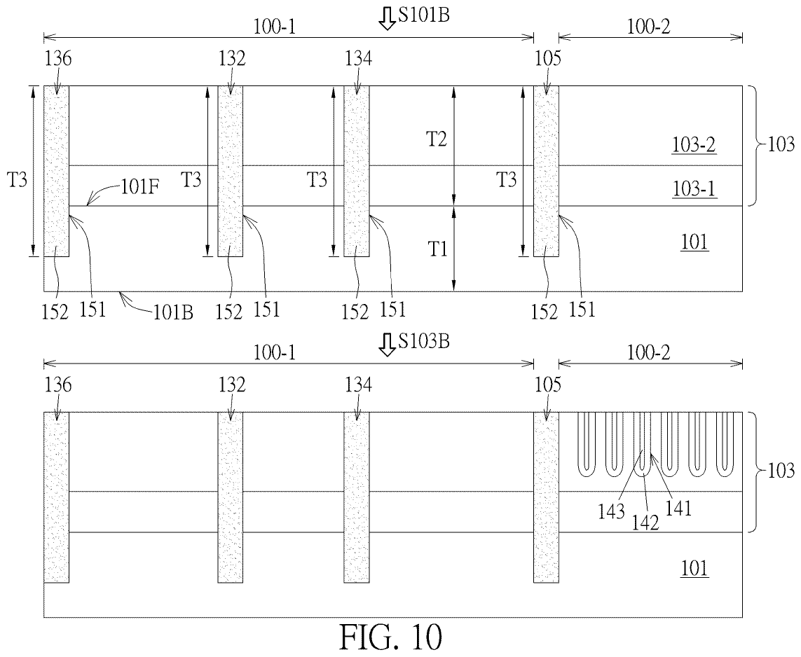

FIG. 10 shows schematic cross-sectional views of some intermediate stages of a method for fabricating the semiconductor structure 100 of FIG. 2 according to another embodiment of the present disclosure. Referring to FIG. 10, in step S101B, before the grinding process of step S119 in FIG. 7, a first sub-DTI structure 132, a second sub-DTI structure 134 and a third sub-DTI structure 136 are formed in the epitaxial stack 103 and the base 101. After the N-LDMOS transistor 111, the P-LDMOS transistor 113 and the CMOS transistor 115 are formed in the epitaxial stack 103 of the first area 100-1, the first sub-DTI structure 132 is located between the N-LDMOS transistor 111 and the P-LDMOS transistor 113. The second sub-DTI structure 134 is located between the P-LDMOS transistor 113 and the CMOS transistor 115. The third sub-DTI structure 136 isolates the N-LDMOS transistor 111 from other components in the first area 100-1. In one embodiment, these sub-DTI structures and the DTI structure 105 are formed simultaneously. The deep trenches 151 of these sub-DTI structures and the deep trench 151 of the DTI structure 105 may have the same depth T3 and the same width. Moreover, the filling material 152 of these sub-DTI structures and the filling material 152 of the DTI structure 105 may have the same composition.

Still referring to FIG. 10, in step S103B, multiple trenches 141 of the VDMOS transistor are formed by etching in the epitaxial stack 103 of the second area 100-2. A dielectric liner 142 is conformally formed in each trench 141, and these trenches 141 are filled with a semiconductor material 143 such as polysilicon by deposition and CMP processes, where the dielectric liner 142 surrounds the semiconductor material 143.

Thereafter, the aforementioned steps S107 in FIG. 4 to step S125 in FIG. 9 are implemented to complete the semiconductor structure 100 of FIG. 2. In this embodiment, after the grinding process of step S119 in FIG. 7 is completed, the DTI structure 105, the first sub-DTI structure 132, the second sub-DTI structure 134, and the third sub-DTI structure 136 are all exposed simultaneously. In addition, after the patterned isolation layer 107 is formed in step S121 to step S123 of FIG. 8, the bottom surfaces of the first sub-DTI structure 132, the second sub-DTI structure 134 and the third sub-DTI structure 136 are all in direct contact with the patterned isolation layer 107. In a top view, the boundary of the patterned isolation layer 107 extends beyond the boundary of the DTI structure 105.

According to some embodiments of the present disclosure, the DTI structure is formed to penetrate the epitaxial layer and the base, and the patterned isolation layer is formed on the back side of the base. The DTI structure and the patterned isolation layer together constitute a local isolation region to surround the lateral devices in the first area, such as the N-LDMOS transistor, the P-LDMOS transistor and the CMOS transistors. In addition, an n-type heavily doped semiconductor base is used as the drain region of the vertical device in the second area, such as the VDMOS transistor. The DTI structure and the patterned isolation layer effectively prevent current in the vertical device from flowing through the base to the lateral devices, thereby providing good electrical isolation between the vertical device and the lateral devices in a monolithic chip. Therefore, the semiconductor structures of the present disclosure prevent the lateral devices from being affected by high potentials of the vertical device, and also avoid electrostatic discharge (ESD) latch-up effects caused by current noise from the vertical device.

In addition, while only a junction isolation region is formed in the epitaxial layer as a local isolation region, increasing the breakdown voltage (BVon) of a parasitic bipolar junction transistor (BJT) to satisfy the breakdown voltage (BVceo) requirements of the LDMOS transistor usually requires increasing the epitaxial layer thickness. However, the junction isolation region depth is limited by the ion implantation energy, thus requiring a reduction in epitaxial layer thickness. According to the semiconductor structures of the present disclosure, the DTI structure and the patterned isolation layer serve as a local isolation region, thus satisfying the breakdown voltage (BVceo) requirements of the LDMOS transistor without issue. Therefore, in the semiconductor structures of the present disclosure, the epitaxial layer thickness can be reduced, and the on-state resistance (Ron) of the VDMOS transistor is also reduced.

Moreover, in the semiconductor structures of the present disclosure, because the patterned isolation layer is formed on the backside of the base, it does not affect the epitaxial quality of the epitaxial layer, nor cause step-height issues in the epitaxial layer of different areas. This is beneficial for subsequent multiple processes performed on the epitaxial layer. For example, the accuracy of the exposure process and the uniformity of grinding, etching and other processes are all improved. Compared with a conventional method using smart-cut and etching processes to form a local oxidation region, followed by growing an epitaxial layer on the local oxidation region, the embodiments of the present disclosure do not have epitaxial defects and step-height issues. In addition, the semiconductor structures of the present disclosure can further increase the thickness of the patterned isolation layer to meet the high-voltage requirements of the vertical power device without causing step-height issues in the epitaxial layer, and are thus more suitable for higher-voltage applications (e.g., greater than 80V).

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a base, having a first conductivity type;
an epitaxial layer, disposed above the base;
a deep trench isolation structure, penetrating the epitaxial layer and the base, wherein the deep trench isolation structure surrounds a first area, and a second area is located outside the deep trench isolation structure;
a patterned isolation layer, disposed on a bottom surface of the base, and having an opening to expose the base in the second area; and
a conductive layer, disposed under the patterned isolation layer, and electrically connected to the base through the opening.

2. The semiconductor structure of claim 1, further comprising:
a lateral device, disposed in the epitaxial layer of the first area; and
a vertical device, disposed in the epitaxial layer of the second area, wherein the base in the second area constitutes a drain region of the vertical device.

3. The semiconductor structure of claim 2, further comprising a buried layer having a second conductivity type, disposed in the epitaxial layer and directly below the lateral device.

4. The semiconductor structure of claim 2, further comprising a sub-deep trench isolation structure disposed between the lateral device and another lateral device.

5. The semiconductor structure of claim 4, wherein the sub-deep trench isolation structure penetrates the epitaxial layer and the base, and a bottom surface of the sub-deep trench isolation structure is in direct contact with a top surface of the patterned isolation layer.

6. The semiconductor structure of claim 1, wherein a bottom surface of the deep trench isolation structure is in direct contact with a top surface of the patterned isolation layer, and in a top view, a boundary of the patterned isolation layer is beyond a boundary of the deep trench isolation structure.

7. The semiconductor structure of claim 1, wherein the conductive layer comprises a metal layer covering a bottom surface and a side surface of the patterned isolation layer, and the conductive layer is in direct contact with the base in the second area.

8. The semiconductor structure of claim 1, wherein the base comprises an n-type heavily doped semiconductor base.

9. The semiconductor structure of claim 1, wherein the deep trench isolation structure comprises a deep trench filled up with an insulating material, and a composition of the patterned isolation layer comprises the insulating material.

10. The semiconductor structure of claim 1, wherein the deep trench isolation structure comprises:
a deep trench;
a dielectric layer, lining inner sidewalls of the deep trench; and
a semiconductor material, filling up the deep trench,
wherein a bias voltage of the deep trench isolation structure is a floating potential, or the deep trench isolation structure is configured to be connected to a ground voltage.

11. A method of fabricating a semiconductor structure, comprising:
providing a base having a first conductivity type and comprising a first surface opposite to a second surface;
forming an epitaxial layer on the first surface of the base;
forming a deep trench isolation structure in the epitaxial layer and the base, wherein the deep trench isolation structure surrounds a first area, and a second area is located outside the deep trench isolation structure;
performing a grinding process on the second surface of the base to thin the base and to expose the deep trench isolation structure;
depositing a isolation material layer on the second surface of the base after the base is thinned, wherein the isolation material layer is in direct contact with a bottom surface of the deep trench isolation structure;
patterning the isolation material layer to form a patterned isolation layer having an opening to expose the base in the second area; and
forming a conductive layer under the patterned isolation layer, wherein the conductive layer is electrically connected to the base through the opening.

12. The method of claim 11, further comprising:
forming a lateral device in the epitaxial layer of the first area before the grinding process; and
forming a vertical device in the epitaxial layer of the second area before the grinding process.

13. The method of claim 12, wherein after the base is thinned, the base in the second area constitutes a drain region of the vertical device.

14. The method of claim 12, further comprising forming a buried layer in the epitaxial layer by an ion implantation process, wherein the buried layer has a second conductivity type and is located directly below the lateral device.

15. The method of claim 12, further comprising forming a sub-deep trench isolation structure in the epitaxial layer and the base before the grinding process, wherein the sub-deep trench isolation structure is located between the lateral device and another lateral device.

16. The method of claim 15, wherein the deep trench isolation structure and the sub-deep trench isolation structure are formed simultaneously, and the deep trench isolation structure and the sub-deep trench isolation structure are exposed by the grinding process.

17. The method of claim 11, wherein forming the deep trench isolation structure comprises:
forming a deep trench by an etching process to penetrate the epitaxial layer, wherein a bottom surface of the deep trench is located in the base; and
filling the deep trench with an insulating material,
wherein the grinding process removes a portion of the insulating material, and after the grinding process, the deep trench isolation structure has a depth less than a depth of the deep trench.

18. The method of claim 11, wherein forming the deep trench isolation structure comprises:
forming a deep trench by an etching process to penetrate the epitaxial layer, wherein a bottom surface of the deep trench is located in the base;
conformally depositing a dielectric layer in the deep trench; and
filling the deep trench with a semiconductor material, wherein the dielectric layer surrounds the semiconductor material, and
wherein the grinding process removes a portion of the dielectric layer and a portion of the semiconductor material, after the grinding process, the deep trench isolation structure has a depth less than a depth of the deep trench, and a bias voltage of the deep trench isolation structure is a floating potential, or the deep trench isolation structure is configured to be connected to a ground voltage.

19. The method of claim 11, wherein forming the conductive layer comprises depositing a metal layer on the second surface of the base after the base is thinned and the patterned isolation layer is formed, wherein the conductive layer covers a bottom surface and a side surfaces of the patterned isolation layer, and fills up the opening to be in direct contact with the base in the second area.

20. The method of claim 11, wherein the patterned isolation layer is in direct contact with a bottom surface of the deep trench isolation structure, and in a top view, a boundary of the patterned isolation layer is beyond a boundary of the deep trench isolation structure.
